(19) United States
(12) Patent Application Publication
(10) Pub. No.: US 2007/0228541 A1
(43) Pub. Date: Oct. 4, 2007

(54) Method for fabricating chip package structure

(75) Inventors: Chi Chih Lin, Pingjhen City (TW); Bo Sun, Pingjhen City (TW); Hung Jen Wang, Gueishan Township (TW); Jen Feng Tseng, Jhongli City (TW)

Correspondence Address: ABELMAN, FRAYNE & SCHWAB, 666 THIRD AVENUE, 10TH FLOOR, NEW YORK, NY, 10017, US

(73) Assignee: TAIWAN SOLUTIONS SYSTEMS CORP.

(21) Appl. No.: 11/807,680

(22) Filed: May 29, 2007

(30) Foreign Application Priority Data
Aug. 12, 2005 (TW) 94143281

(51) Int. Cl. H01L 23/06

(52) U.S. Cl. 257/684

(57) ABSTRACT

A method for fabricating a chip package structure is disclosed. One or plural patterned plates are used to fabricate the inner circuits and the outer circuits, and some fabricating steps can be proceeded repeatedly to form a stack structure, and after a protective layer is formed, the carrier is removed. Using the plate as a mask to fabricate the circuits can enhance the yield and simplify the fabricating processes of the package. Further, the removed carrier can be recycled to reduce the production cost.

### BACKGROUND OF THE INVENTION

1. Field of the Invention

The present invention relates to the method for fabricating the semiconductor, and more especially, to the method for fabricating the chip package structure.

2. Background of the Related Art

Because the increasing functions of the computer and the network communication, the semiconductor technique must satisfy the demands of diversification, portability, light, thin and compact trends. In the chip package manufacturing industry, the traditional manufacturing process needs to be improved and toward the processes with high power, high density and high precision. Besides, in the present day, the circuits on the printed-circuit-board (PCB) are usually fabricated by the lithography processes, which have many complicated steps to be unsuitable for the demands of the semiconductor science and technology.

### SUMMARY OF THE INVENTION

In order to solve the foregoing problems, one object of this invention is to provide a method for fabricating a chip package structure, wherein at least one patterned plate set on the carrier is used to replace the conventional lithography procedure, to simplify the conventional package procedure and enhance the yield, which may satisfy the demands of the present semiconductor science and technology.

One object of this invention is to provide a method for fabricating the chip package structure, which can be stacked in order to form a stack structure and then to fabricate the multi-layer PCB, and so as to be suitable for varied semiconductor packages.

One object of this invention is to provide a method for fabricating the chip package structure, which can be performed by using the existing processes of the package industry without increasing additional apparatus or process. Furthermore, the removed carrier can be recycled to reduce the whole package cost.

Accordingly, one embodiment of the present invention provides a method for fabricating a chip package structure, which includes: providing a carrier with a first patterned plate set thereon, wherein the first patterned plate exposes a portion the carrier; forming at least one conductive layer on an exposed portion of the carrier; then removing the first patterned plate; next, setting a second patterned plate on the carrier, wherein the second patterned plate partially exposes at least one portion of the conductive layer or a portion of the carrier; forming a metal layer on an exposed portion of the conductive layer or the carrier; then removing the second patterned plate; setting at least one die on a portion of the metal layer and electrically connecting the die and the metal layer; forming a protective layer to cover the die; and removing the carrier.

### BRIEF DESCRIPTION OF THE DRAWINGS

FIG. 1(a) to FIG. 1(l) are cross-sectional diagrams illustrating the method for fabricating a chip package structure in accordance with an embodiment of the present invention;

FIG. 2(a) to FIG. 2(n) are cross-sectional diagrams illustrating the method for fabricating a chip package structure in accordance with another embodiment of the present invention;

FIG. 3(a) to FIG. 3(k) are cross-sectional diagrams illustrating the method for fabricating a chip package structure in accordance with another embodiment of the present invention; and

FIG. 4(a) to FIG. 4(m) are cross-sectional diagrams illustrating the method for fabricating a chip package structure in accordance with another embodiment of the present invention.

### DETAILED DESCRIPTION OF THE INVENTION

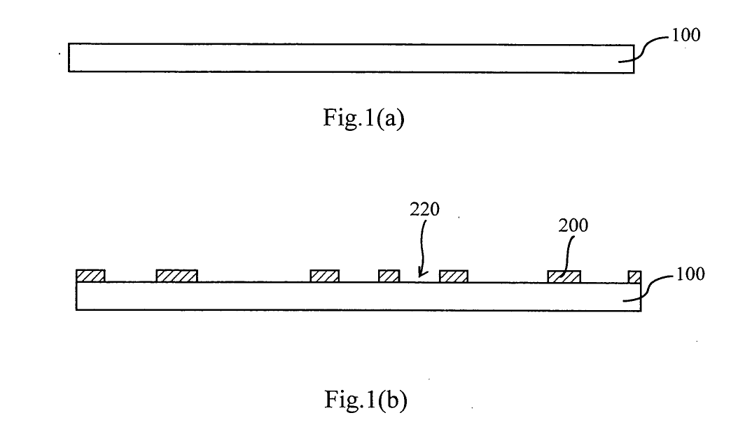

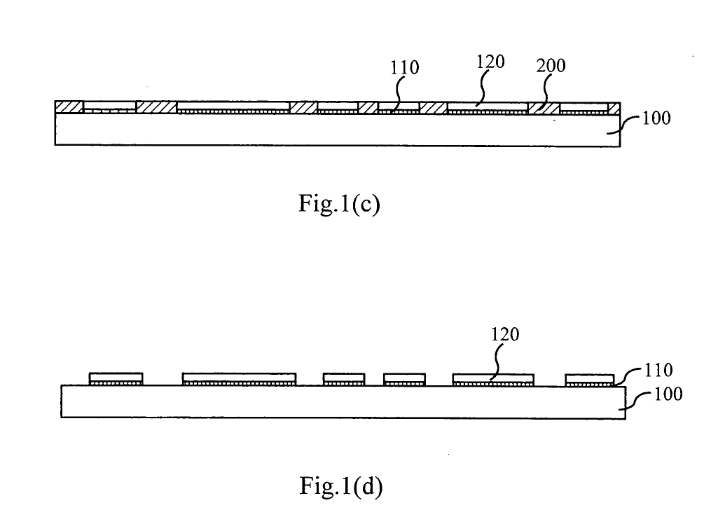

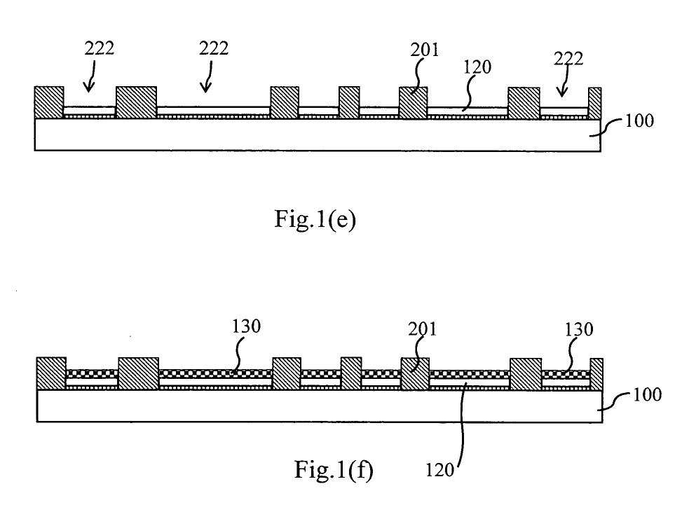

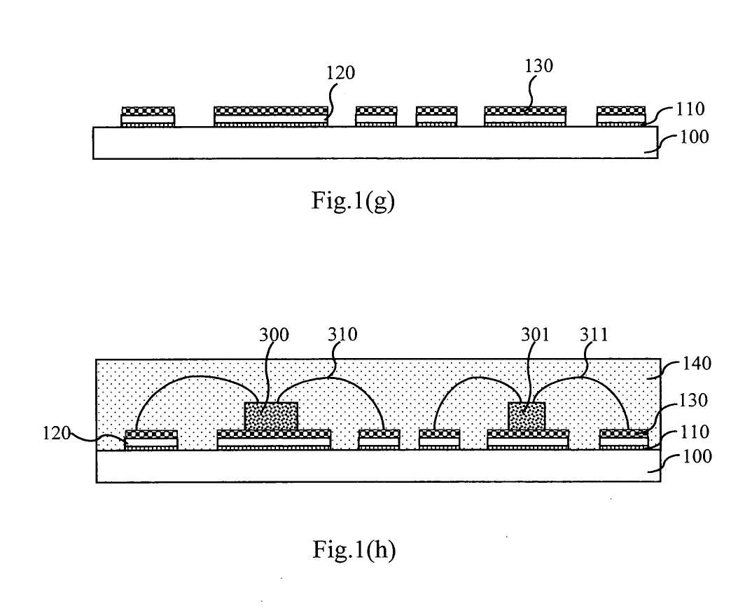

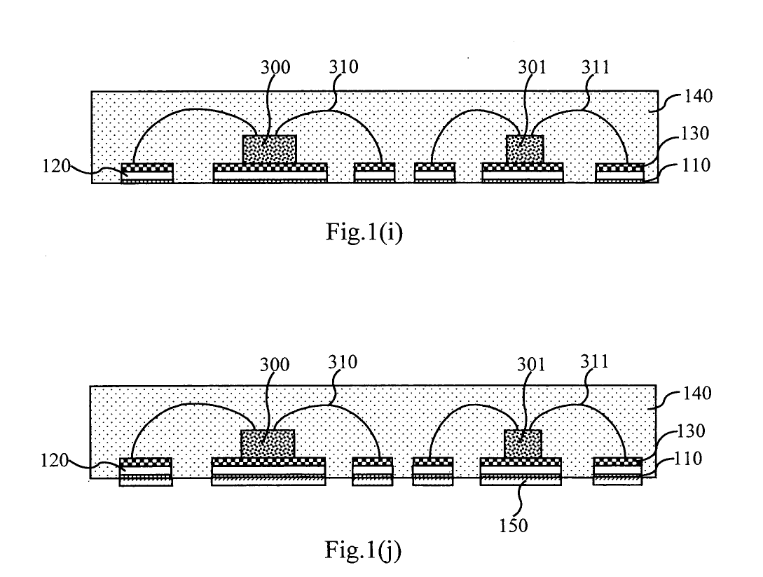

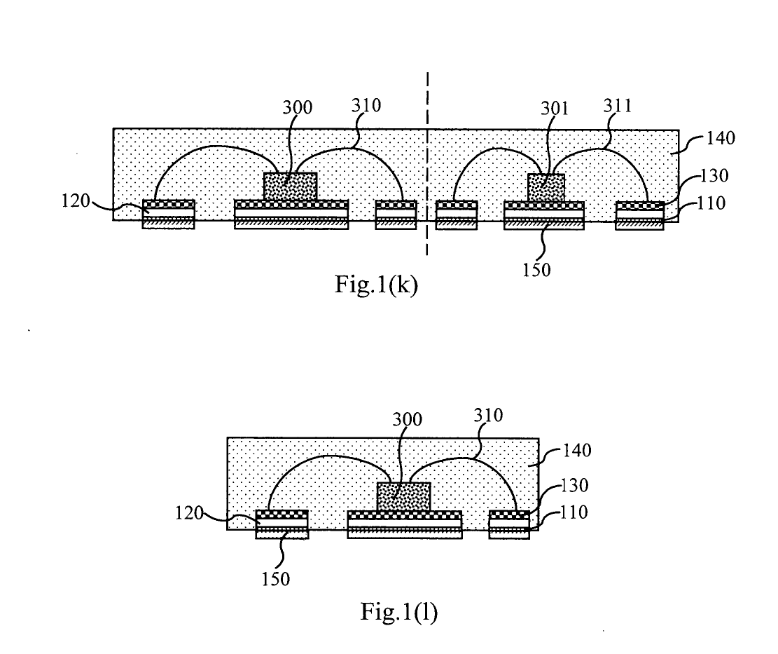

The following embodiments are used to explain the method for fabricating a chip package structure, wherein FIG. 1(a) to FIG. 1(l) are cross-sectional diagrams illustrating the method for fabricating a chip package structure in accordance with an embodiment of the present invention.

Please refer to FIG. 1(a), a carrier 100 is provided at first and the carrier 100 is made of metal, glass, ceramics or composite materials in one embodiment. Next, a first patterned plate 200 is set on the carrier 100 to form a first patterned cavity 220 and exposes a portion of the carrier 100 as shown in FIG. 1(b). Then, as shown in FIG. 1(c), the first patterned plate 200 is applied as a mask to form at least one conductive layer 120 on the carrier 100 by a conventional way, such as the way of pasting, laminating, printing, spray coating, spin coating, evaporation, sputtering, electroless plating or electroplating. In one embodiment, before the conductive layer 120 is formed, at least one adhesive layer 110 is formed on the carrier 100 by pasting, printing, spin coating, sputtering or electroless plating to make the adhesive layer 110 between the carrier 100 and the conductive layer 120 later, wherein the adhesive layer 110 is made of the conductive material. Further, as shown in FIG. 1(d) and FIG. 1(e), the first patterned plate 200 is removed and a second patterned plate 201 is set on the carrier 100 to form a second patterned cavity 222 on the carrier 100 and/or the conductive layer 120. Then, please refer to FIG. 1(f), the second patterned plate 201 is applied as a mask for metal surface treatment to form at least one metal layer 130 in the second patterned cavity 222, wherein the metal layer 130 is made of silver, tin, nickel-palladium-gold (NiPdAu) or nickel-gold (NiAu) and the metal layer 130 is used as a conductive channel between the conductive layer 120 and the die which will be set later. Wherein, the first patterned plate 200 and the second patterned plate 201 are made of polymer or metal. In one embodiment, as shown in FIG. 1(f), the metal layer 130 is formed by sputtering, evaporation, electroless plating or electroplating. Next, please refer to FIG. 1(g) and FIG. 1(h), the second patterned plate 201 is removed, and then the dies 300, 301 are set on the conductive layer 120 or the metal layer 130 by a conventional die bonding process, and the dies 300, 301 are electrically connected to the metal layer 130. In one embodiment, the wires 310, 311 are used to electrically connect the dies 300, 301 with the metal layer 130. Then, a molding process is proceeded, wherein a protective layer 140 is used to cover the dies 300, 301, the metal layer 130, the conductive layer 120, the adhesive layer 110 and a portion of the carrier 100. Further, as shown in FIG. 1(i), the carrier 100 is removed by an appropriate way to expose the conductive layer 120 or the adhesive layer 110 and the portion of the protective layer 140. In one embodiment, after the carrier 100 is removed, a plurality of bumps 150 which are made of tin, tin-lead (SnPb), silver, gold, nickel-palladium-gold (NiPdAu) or nickel-gold (NiAu) are formed under the exposed conductive layer 120 or the adhesive layer 110 by an appropriate way, as shown in FIG. 1(j), and so as to electrically connect the bumps 150 to the other electrical apparatus conveniently. Finally, as shown in FIG. 1(k) and FIG. 1(l), a plurality of chip package structures are formed completely by dicing in accordance with a unit of each chip 300 or 301 along the dotted line shown in FIG. 1(k).

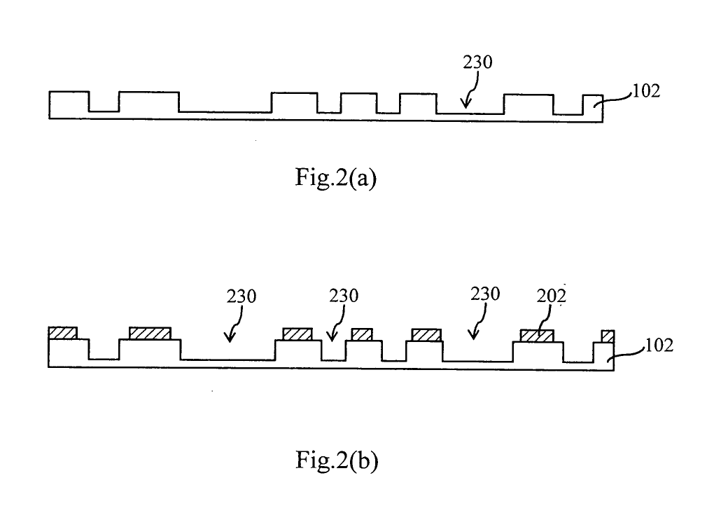

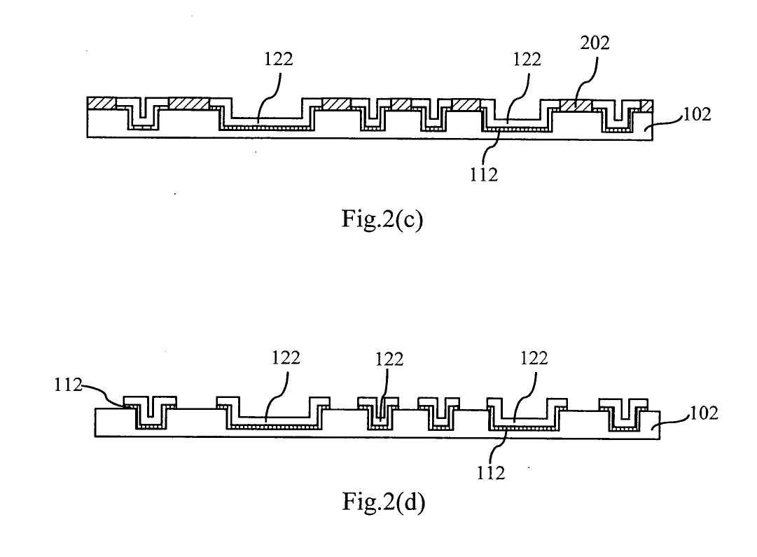

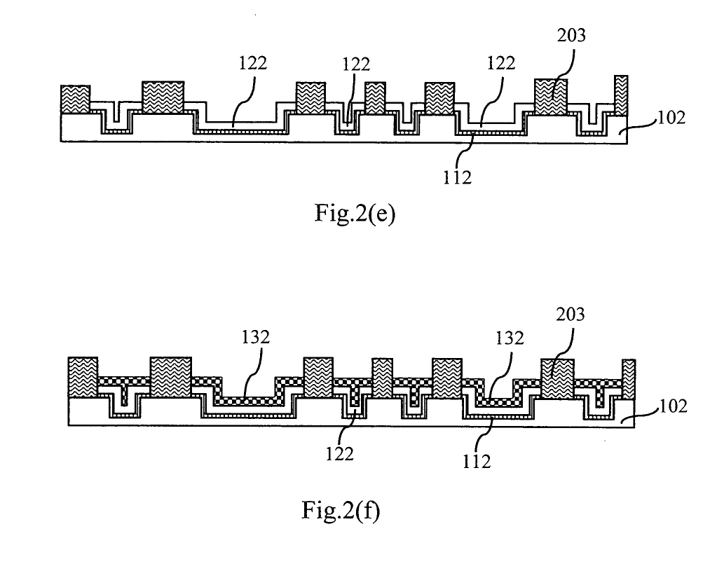

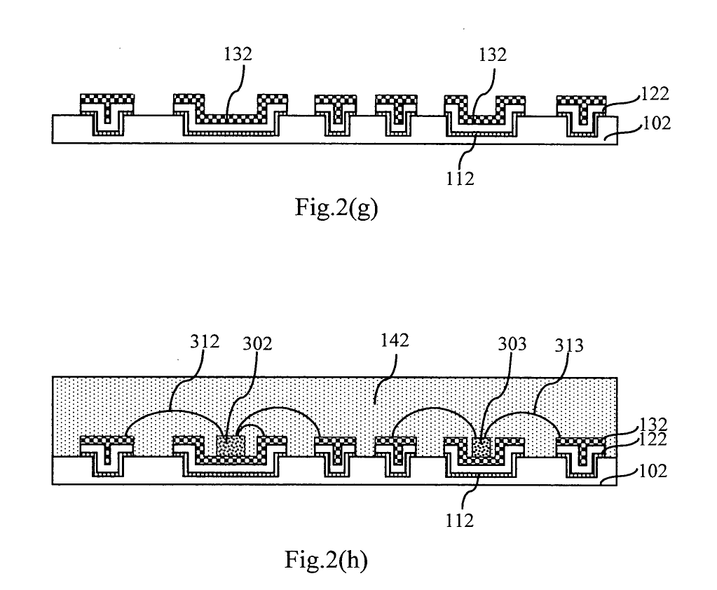

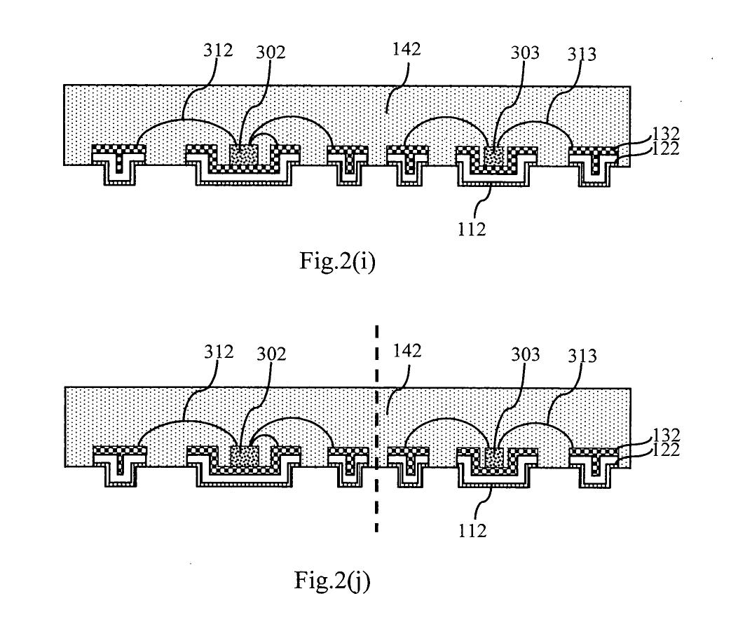

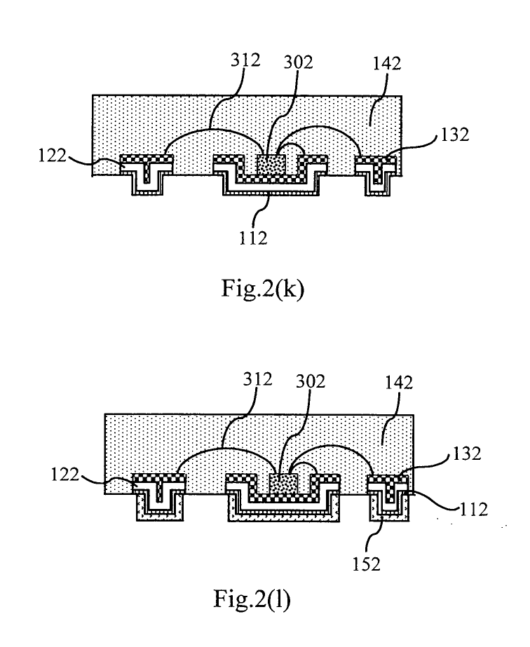

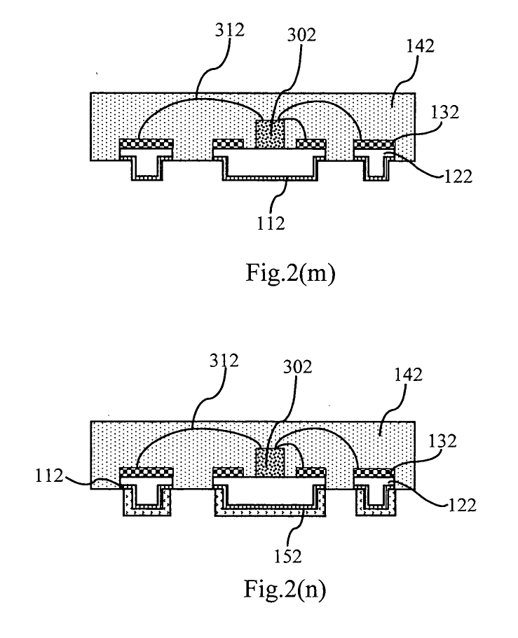

FIG. 2(a) to FIG. 2(n) are cross-sectional diagrams illustrating the method for fabricating a chip package structure in accordance with another embodiment of the present invention. Please refer to FIG. 2(a) at first, a carrier 102 made of metal, glass, ceramics or composite materials is provided, and at least one cavity 230 is formed on the carrier 102 by the penetration controlling way, such as the punching, the drilling or the etching. Next, as shown in FIG. 2(b), a first patterned plate 202 is set on the carrier 102 to expose a portion of the carrier 102 or the cavity 230, wherein the first patterned plate 202 is made of polymer or metal. Next, at least one conductive layer 122 is formed on an exposed portion of the carrier 102 or the cavity 230 by a conventional way, such as the way of pasting, laminating, printing, spray coating, spin coating, evaporation, sputtering, electroless plating or electroplating. In one embodiment, before the conductive layer 122 is formed, at least one adhesive layer 112 is formed on the carrier 102 by pasting, printing, spin coating, sputtering or electroless plating and is set between the carrier 102 and the conductive layer 122 later, wherein the adhesive layer 112 is made of the conductive material. Further, as shown in FIG. 2(c) and FIG. 2(d), the first patterned plate 202 is removed. Next, please refer to FIG. 2(e), FIG. 2(f) and FIG. 2(g), a second patterned plate 203 is set on the exposed carrier 102 as a mask for metal surface treatment to form a metal layer 132 on conductive layer 122, wherein the metal layer 132 is used to be as a conductive channel between the conductive layer 122 and the die which will be set later. The second patterned plate 203 is made of the polymer or the metal, and the metal layer 132 is made of silver, tin, copper, nickel-palladium-gold (NiPdAu) or nickel-gold (NiAu). After the metal layer 132 is formed, the second patterned plate 203 is removed to form a structure shown in FIG. 2(g), which can be provided as the inner/outer circuits of the PCB. Furthermore, please refer to FIG. 2(h), the dies 302, 303 are set on the conductive layer 122 or the metal layer 132 by a conventional die bonding process, and the dies 302, 303 are electrically connected to the metal layer 132. Then, a protective layer 142 is formed to cover the dies 302, 303, the metal layer 132, the conductive layer 122, the adhesive layer 112 and the exposed carrier 102. In one embodiment, the wires 312, 313 are used to electrically connect the dies 302,303 with the metal layer 132. Then, as shown in FIG. 2(i), the carrier 102 is removed by an appropriate way to expose the conductive layer 122 or the adhesive layer 112 and one portion of the protective layer 142. Finally, as shown in FIG. 2(j) and FIG. 2(k), a plurality of chip package structures are formed completely by dicing in accordance with a unit of each chip 302 or 303 along the dotted line shown in FIG. 2(j). In one embodiment, after the carrier 102 is removed, a plurality of bumps 152 which are made of tin, tin-lead (SnPb), silver, gold, nickel-palladium-gold (NiPdAu) or nickel-gold (NiAu) are formed under the exposed conductive layer 122 or the adhesive layer 112 by an appropriate way, as shown in FIG. 2(l). Please refer to FIG. 2(m), in another embodiment, in the fabricating process, the cavity 230 can further be filled with the adhesive layer 112 or the conductive layer 122 and a portion of the carrier 102 can be covered by the adhesive layer 112 or the conductive layer 122, wherein structures of the cavity 230 and the carrier 102 are shown in FIG. 2(b), and then the bumps 152 which are made of tin, tin-lead (SnPb), silver, gold, nickel-palladium-gold (NiPdAu) or nickel-gold (NiAu) are formed under the exposed conductive layer 122 or the adhesive layer 112, as shown in FIG. 2(n), and so as to electrically connect the bumps 152 to the other electrical apparatus conveniently.

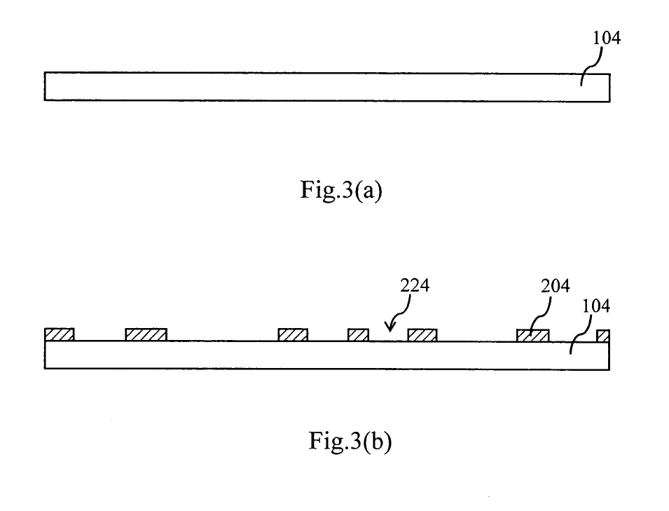

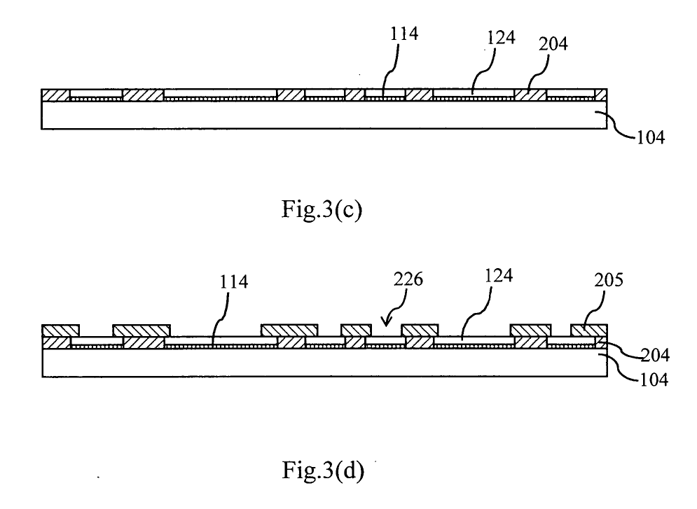

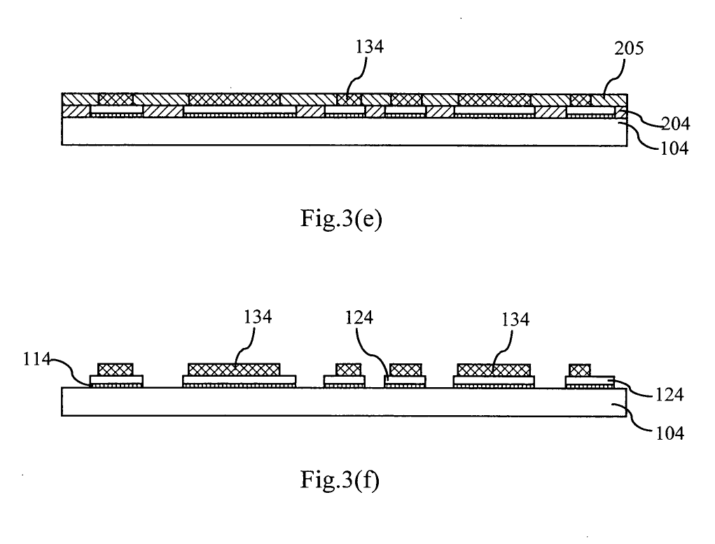

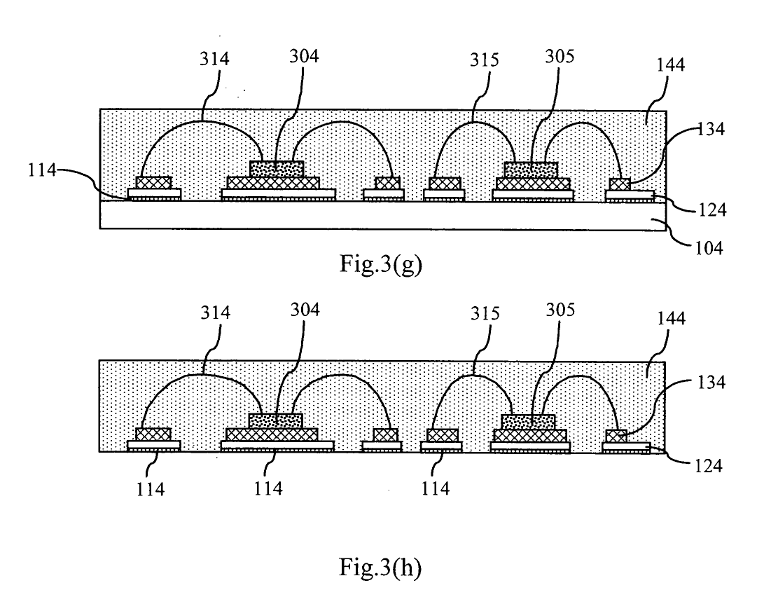

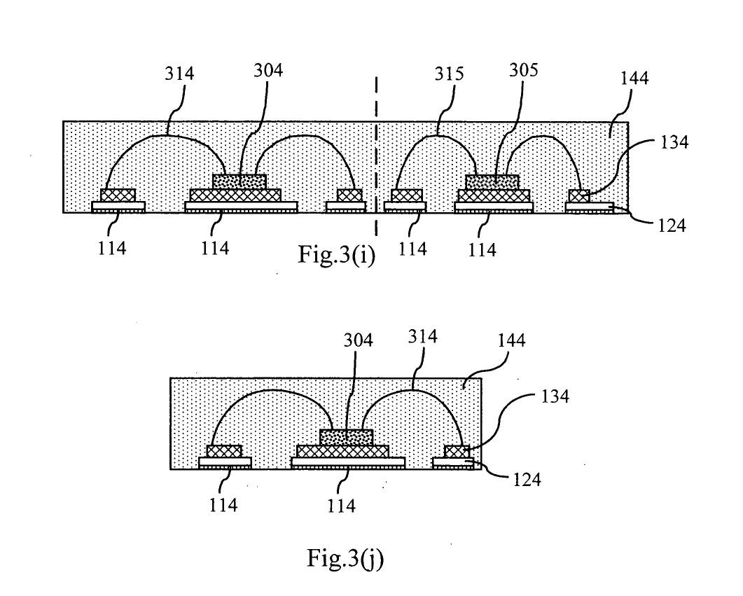

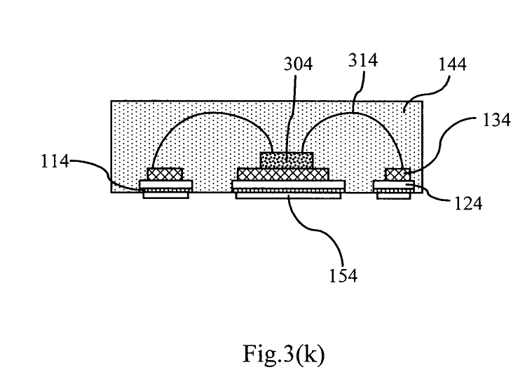

Continuously, please refer to FIG. 3(a) to FIG. 3(k), which are cross-sectional diagrams illustrating the method for fabricating a chip package structure in accordance with another embodiment of the present invention. In one embodiment, a carrier 104 is provided at first and the carrier 104 is made of metal, glass, ceramics or composite materials in one embodiment. Next, as shown in FIG. 3(b), a first patterned plate 204 is set on the carrier 104 to form a first patterned cavity 224 thereon. Then, as shown in FIG. 3(c), the first patterned plate 204 is applied as a mask to form at least one conductive layer 124 on the carrier 104 by the way of pasting, laminating, printing, spray coating, spin coating, evaporation, sputtering, electroless plating or electroplating, wherein the first patterned plate 204 is made of polymer or metal. In one embodiment, before the conductive layer 124 is formed, at least one adhesive layer 114 is formed on the carrier 104 by pasting, printing, spin coating, sputtering or electroless plating and is set between the carrier 104 and the conductive layer 124 later, wherein the adhesive layer 114 is made of conductive material. Next, please refer to FIG. 3(d), a second patterned plate 205 is set on the first patterned plate 204 to form a second patterned cavity 226 in a portion of the conductive layer 124, wherein the second patterned plate 205 is made of polymer or metal. Continuously, as shown in FIG. 3(e), the second patterned plate 205 is applied as a mask for metal surface treatment to form at least one metal layer 134 in the second patterned cavity 226 by sputtering, evaporation, electroless plating or electroplating, wherein the metal layer 134 is made of silver, tin, nickel-palladium-gold (NiPdAu) or nickel-gold (NiAu) and metal layer 134 is used as a conductive channel between the conductive layer 124 and the die which will be set later. Please refer to FIG. 3(f), the first patterned plate 204 and the second patterned plate 205 are removed respectively to expose the metal layer 134, one portion of the conductive layer 124, the adhesive layer 114 and one portion of the carrier 104. Furthermore, please refer to FIG. 3(g), one or more dies are set on the metal layer 134 by the conventional die bonding process, wherein the dies 304, 305 can have different operation functions. Next, in one embodiment, an electric conduction structure, such as the wires 314, 315, is used to electrically connect the dies 304, 305 with the metal layer 134. Then, a molding process is proceeded, wherein a protective layer 144 is used to cover the dies 304, 305, the wires 314, 315, the metal layer 134, the conductive layer 124, the adhesive layer 114 and one portion of the exposed carrier 104. Then, as shown in FIG. 3(h), the carrier 104 is removed by an appropriate way to expose one portion of the protective layer 144, the conductive layer 124 or the adhesive layer 114. Please refer to FIG. 3(i) and FIG. 3(j), a plurality of chip package structures are formed by dicing in accordance with a unit of each chip. In one embodiment, after the carrier 104 is removed, a plurality of bumps 154 which are made of tin, tin-lead (SnPb), silver, gold, nickel-palladium-gold (NiPdAu) or nickel-gold (NiAu) are formed under the exposed conductive layer 124 or the adhesive layer 114 by electroplating, evaporation, sputtering, electroless plating or screen printing, as shown in FIG. 3(k), and so as to electrically connect the bumps 150 to the other electrical apparatus conveniently.

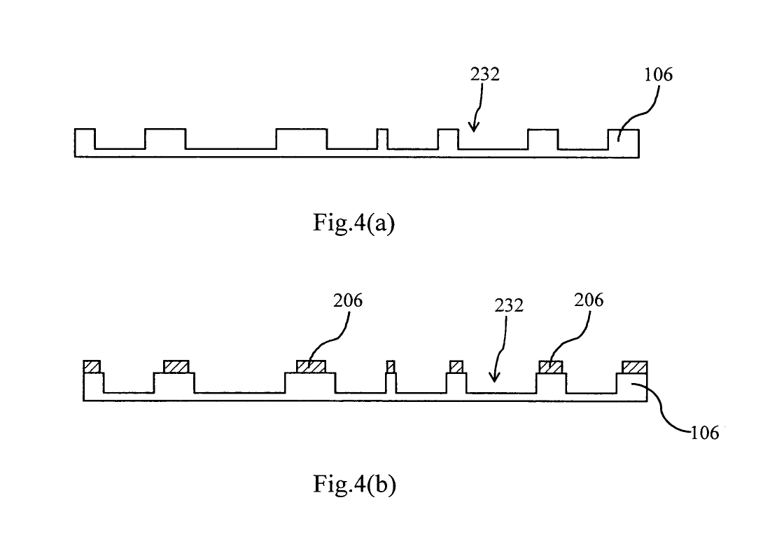

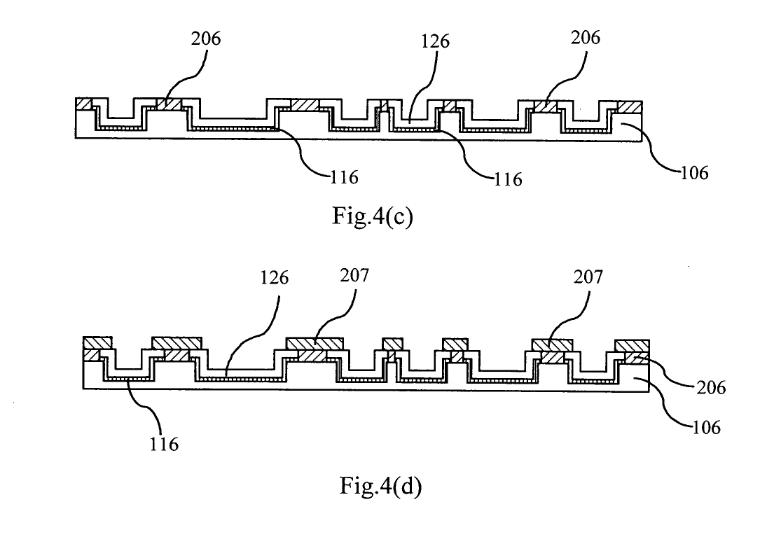

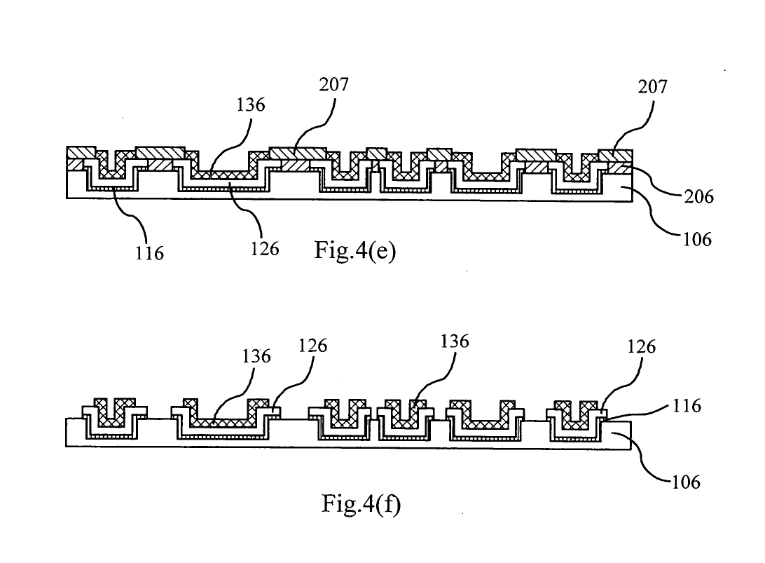

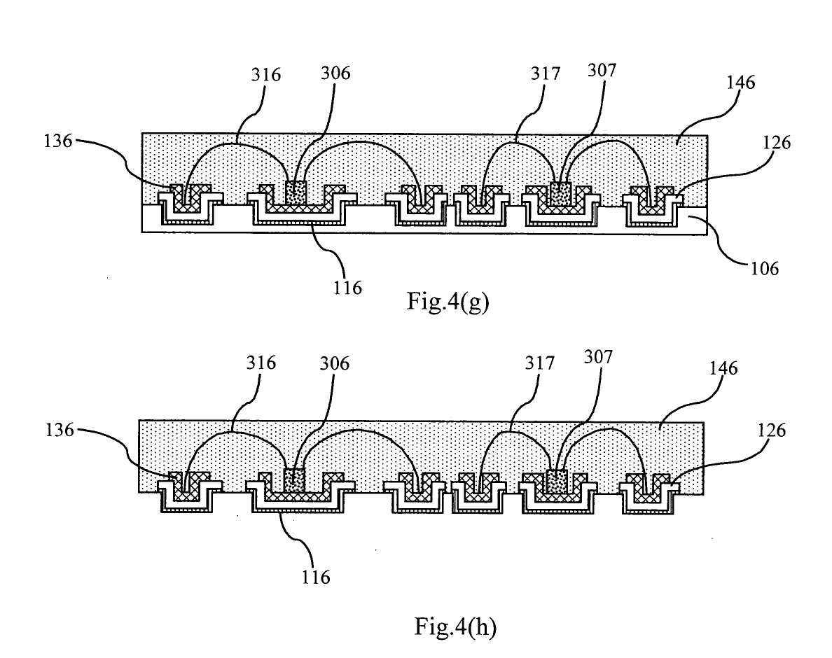

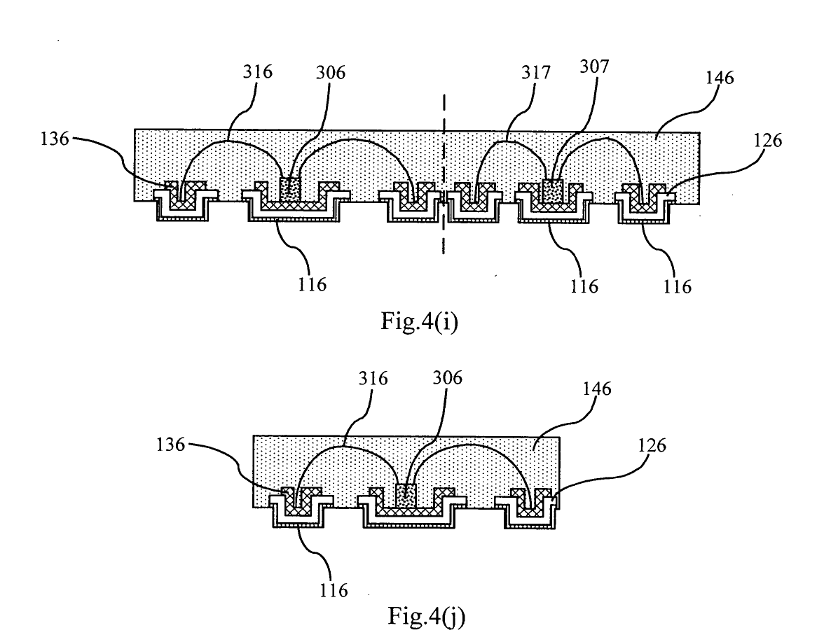

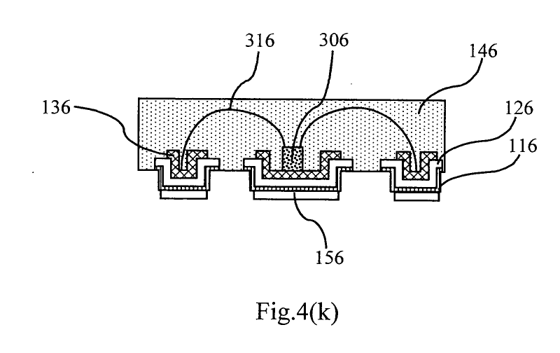

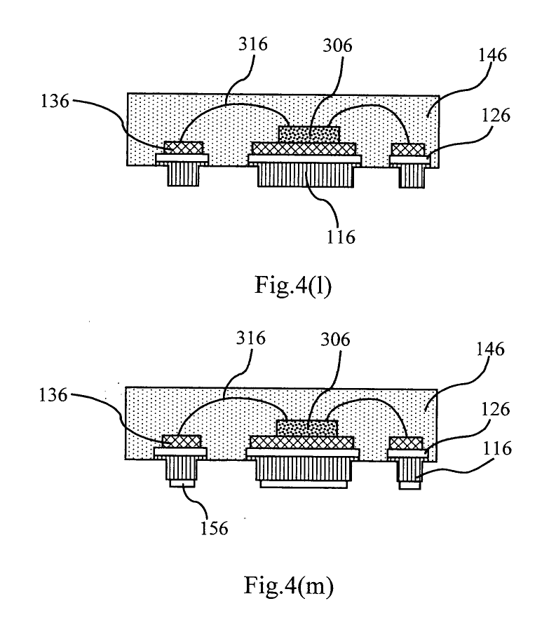

Furthermore, please refer to FIG. 4(a) to FIG. 4(k), which are cross-sectional diagrams illustrating the method for fabricating a chip package structure in accordance with another embodiment of the present invention. Please refer to FIG. 4(a) at first, a carrier 106 is provided, wherein at least one cavity 232 is formed on the carrier 106 by the penetration controlling way, such as the punching, the drilling or the etching. Next, as shown in FIG. 4(b), a first patterned plate 206 is set on the carrier 106 to expose a portion of the carrier 106 or the cavity 232. Next, please refer to FIG. 4(c), the first patterned plate 206 is applied as a mask to form at least one conductive layer 126 on the carrier 106 by the way of pasting, laminating, printing, spray coating, spin coating, evaporation, sputtering, electroless plating or electroplating. In one embodiment, before the conductive layer 126 is formed, at least one adhesive layer 116 is formed on the carrier 106 by pasting, printing, spin coating, sputtering or electroless plating and is set between the carrier 106 and the conductive layer 126 later, wherein the adhesive layer 116 is made of conductive material. Next, please refer to FIG. 4(d), a second patterned plate 207 is set on the first patterned plate 206 to expose one portion of the conductive layer 126, wherein the first patterned plate 206 and the second patterned plate 207 are made of polymer or metal. Continuously, as shown in FIG. 4(e), the second patterned plate 207 is applied as a mask to form at least one metal layer 136 on the exposed portion of the conductive layer 126 by sputtering, evaporation, electroless plating or electroplating, wherein the metal layer 136 is made of silver, tin, nickel-palladium-gold (NiPdAu) or nickel-gold (NiAu) and the metal layer 136 is used to be as a conductive channel between the conductive layer 126 and the die which will be set later. Please refer to FIG. 4(f), the first patterned plate 206 and the second patterned plate 207 are removed, respectively. Furthermore, please refer to FIG. 4(g), one or more dies are set on the metal layer 136 by the conventional die bonding process, wherein the dies 306, 307 can have different operation functions. Next, in one embodiment, an electric conduction structure, such as the wires 316, 317, is used to electrically connect the dies 306, 307 with the metal layer 136. Then, a molding process is proceeded, wherein a protective layer 146 is used to cover the dies 306, 307, the wires 316, 317, the metal layer 136, the conductive layer 126, the adhesive layer 116 and the portion of the exposed carrier 106. Then, as shown in FIG. 4(h), the carrier 106 is removed by an appropriate way to expose one portion of the protective layer 146, the conductive layer 126 or the adhesive layer 116. Then, as shown in FIG. 4(h), the carrier 106 is removed by an appropriate way to expose one portion of the protective layer 146, the conductive layer 126 or the adhesive layer 116. Please refer to FIG. 4(i) and FIG. 4(j), a plurality of chip package structures are formed by dicing in accordance with a unit of each chip. In one embodiment, after the carrier 106 is removed, a plurality of bumps 156 are formed under the exposed conductive layer 126 or the adhesive layer 116 by electroplating, evaporation, sputtering, electroless plating or screen printing, as shown in FIG. 4(k), and so as to electrically connect the bumps 156 to the other electrical apparatus conveniently. In another embodiment, please refer to FIG. 4(l), the cavity 232 can further be filled with the adhesive layer 116 and a portion of the carrier 106 can be covered by the adhesive layer 116, wherein the structures of the cavity 232 and the carrier 106 are shown in FIG. 4(b), and then the bumps 156 which are made of tin, tin-lead (SnPb), silver, gold, nickel-palladium-gold (NiPdAu) or nickel-gold (NiAu) are formed under the exposed adhesive layer 116, as shown in FIG. 2(m), and so as electrically connect the bumps 156 to the other electrical apparatus conveniently.

Wherein, in the foregoing embodiments, the steps which happened prior to set the dies 300, 301, 302, 303, 304, 305, 306, 307 can be proceeded repeatedly to form the stack structure.

To sum up, in the fabricating process of the chip package structure in the present invention, the carrier is used as a support to fabricate the ultra-thin package substrate and may further to fabricate the two-sided package substrate. Furthermore, the conductive channel is fabricated by using the patterned plate in the present invention rather than the conventional way of using the lithography, and so as to simplify the conventional package procedure and furthermore to enhance the yield. Further, the fabricating method in the present invention can be performed by using the existing processes of the PCB industry without increasing additional apparatus or process. The removed carrier can be recycled to reduce the whole package cost.

Although the present invention has been explained in relation to its preferred embodiment, it is to be understood that other modifications and variation can be made without departing the spirit and scope of the invention as hereafter claimed.

What is claimed is:

1. A method for fabricating a chip package structure, comprising:
providing a carrier with a first patterned plate set thereon, wherein said first patterned plate exposes a portion of said carrier;
forming at least one conductive layer on an exposed portion of said carrier;
removing said first patterned plate;
setting a second patterned plate on said carrier, wherein said second patterned plate partially exposes at least one portion of said conductive layer or one portion of said carrier;
forming a metal layer on an exposed portion of said conductive layer or said carrier;
removing said second patterned plate;
setting at least one die on a portion of said metal layer and electrically connecting said die and said metal layer;
forming a protective layer to cover said die; and
removing said carrier.

2. The method for fabricating the chip package structure according to claim 1, further comprising forming an adhesive layer between said carrier and said conductive layer.

3. The method for fabricating the chip package structure according to claim 2, wherein said adhesive layer is formed on said carrier by pasting, printing, spin coating, sputtering or electroless plating.

4. The method for fabricating the chip package structure according to claim 2, further comprising forming at least one bump under said adhesive layer after removing said carrier.

5. The method for fabricating the chip package structure according to claim 4, further comprising forming a plurality of said chip package structures by dicing in accordance with each said chip.

6. The method for fabricating the chip package structure according to claim 1, wherein said carrier comprises at least one cavity.

7. The method for fabricating the chip package structure according to claim 6, further comprising forming an adhesive layer between said carrier and said conductive layer.

8. The method for fabricating the chip package structure according to claim 7, wherein said cavity is filled with said adhesive layer and a portion of said carrier is covered by said adhesive layer.

9. The method for fabricating the chip package structure according to claim 8, further comprising forming at least one bump under said adhesive layer after removing said carrier.

10. The method for fabricating the chip package structure according to claim 9, further comprising forming a plurality of said chip package structures by dicing in accordance with each said chip.

11. The method for fabricating the chip package structure according to claim 6, wherein said cavity is filled with said conductive layer and a portion of said carrier is covered by said conductive layer.

12. The method for fabricating the chip package structure according to claim 11, further comprising forming at least one bump under said conductive layer after removing said carrier.

13. The method for fabricating the chip package structure according to claim 12, further comprising forming a plurality of said chip package structures by dicing in accordance with each said chip.

14. The method for fabricating the chip package structure according to claim 1, wherein said conductive layer is formed by pasting; laminating, printing, spray coating, spin coating, evaporation, sputtering, electroless plating or electroplating.

15. The method for fabricating the chip package structure according to claim 1, wherein said metal layer is formed by sputtering, evaporation, electroless plating or electroplating.

16. The method for fabricating the chip package structure according to claim 1, wherein said die is electrically connected to said metal layer by using a plurality of wires.

17. The method for fabricating the chip package structure according to claim 1, further comprising forming at least one bump under said conductive layer after removing said carrier.

18. The method for fabricating the chip package structure according to claim 17, further comprising forming a plurality of said chip package structures by dicing in accordance with each said chip.

19. The method for fabricating the chip package structure according to claim 1, wherein said carrier is made of metal, glass, ceramics or composite materials.

20. The method for fabricating the chip package structure according to claim 1, wherein said first patterned plate is made of polymer or metal.

21. The method for fabricating the chip package structure according to claim 1, wherein said second patterned plate is made of polymer or metal.
